(19) United States
(12) Patent Application Publication
(10) Pub. No.: US 2022/0009428 A1
(43) Pub. Date: Jan. 13, 2022

(54) ELECTRICAL JUNCTION BOX

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventor: Tatsuya Sumida, Yokkaichi-shi, Mie (JP)

(21) Appl. No.: 17/295,846

(22) PCT Filed: Nov. 18, 2019
(86) PCT No.: PCT/JP2019/045014

§ 371 Date: May 20, 2021

(30) Foreign Application Priority Data
Nov. 30, 2018 (JP) 2018-224321

(51) Int. Cl. B60R 16/023; H02G 3/16; H02G 3/08; H05K 9/00

(52) U.S. Cl. CPC B60R 16/0239; H05K 9/0024; H02G 3/081; H02G 3/16

(57) ABSTRACT

An electrical junction box includes a circuit board that has a conductive path and on which electronic components are mounted, a conductive first shield case covering one side of the circuit board, a conductive second shield case covering the opposite side of the circuit board to the one side, a first resin case that covers the first shield case and is made of resin, and a second resin case that covers the second shield case and is made of resin.

### CROSS-REFERENCE TO RELATED APPLICATIONS

This application is the U.S. national stage of PCT/JP2019/045014 filed on Nov. 18, 2019, which claims priority of Japanese Patent Application No. JP 2018-224321 filed on Nov. 30, 2018, the contents of which are incorporated herein.

### TECHNICAL FIELD

Technology relating to an electrical junction box is disclosed in this specification.

### BACKGROUND

Conventionally, electrical junction boxes in which circuit boards are accommodated in cases are known. An electrical junction box disclosed in JP 2014-103747A includes a circuit board on which electrical components such as a relay is mounted, a metal heat dissipation member stacked on the lower side of the circuit board, and a metal case covering the upper side of the heat dissipation member on which the circuit board is stacked. The electrical junction box is provided with a shielding function due to the case and the heat dissipation member of the electrical junction box covering the circuit board.

Incidentally, if a metal case is used as an outer cover of an electrical junction box in order to provide the electrical junction box with a shielding function, it is problematic that the weight of the metal is a barrier to weight reduction of the electrical junction box, and that manufacturing costs tend to increase because the durability of a mold during production is lower than that of a case made of a synthetic resin.

Technology described in this specification has been made based on the above-described circumstances, and aims to reduce manufacturing costs while reducing the weight of an electrical junction box.

### SUMMARY

An electrical junction box described in this specification includes a circuit board that has a conductive path and on which an electronic component is mounted; a conductive first shield case covering one side of the circuit board; a conductive second shield case covering an opposite side of the circuit board to the one side; a first resin case that covers the first shield case and is made of resin; and a second resin case that covers the second shield case and is made of resin.

According to the above-described configuration, both sides of the circuit board are covered by the first shield case and the second shield case, and the outer sides of the first shield case and the second shield case are covered by the resin cases, and thus it is possible to reduce the weight of the electrical junction box compared with a configuration in which a metal case is used as an outer cover of an electrical junction box, while providing both sides of the circuit board with a shielding function. Also, it is possible to use a thin metal plate member for the shield case compared to a configuration in which a shield case is used as an outer cover of an electrical junction box, and thus the shield case can be easily shaped and manufacturing costs can be reduced.

Embodiments of the technology described in this specification preferably have the following features.

The electronic component is provided in plural and includes a high-noise component and a low-noise component whose noise is smaller than that of the high-noise component, and at least one of the first shield case and the second shield case covers a surface of the circuit board so as to include an area where the high-noise component is mounted, which is an area smaller than the entire area of the circuit board.

One of the first shield case and the second shield case includes a plate-shaped lock portion, the other of the first shield case and the second shield case includes a first locking piece and a second locking piece that hold the lock portion therebetween, and the first locking piece and the second locking piece are arranged side-by-side along the lock portion.

The conductive path includes a ground pattern connected to a ground potential, and at least one of the first shield case and the second shield case includes a fastening portion that is screwed to the circuit board and connected to the ground pattern.

At least one of the first shield case and the second shield case includes the fastening portion and an opposing portion that faces the circuit board at an interval, and a step portion is formed between the fastening portion and the opposing portion.

At least one of the first shield case and the second shield case includes a side wall portion that has a plate surface extending in a direction that intersects with a plate surface of the circuit board, and an end portion of the side wall portion on the circuit board side is provided with a clearance between the end portion and a surface of the circuit board.

A capacitor is accommodated between the second shield case and the second resin case.

### Advantageous Effects of Invention

According to technology described in this specification, it is possible to reduce manufacturing costs while reducing the weight of an electrical junction box.

### BRIEF DESCRIPTION OF DRAWINGS

FIG. 1 is a perspective view showing an electrical junction box according to an embodiment.

FIG. 2 is a cross-sectional plan view of the electrical junction box.

FIG. 3 is an enlarged view of a portion shown in FIG. 2.

FIG. 4 is a cross-sectional view taken along A-A in FIG. 2.

FIG. 5 is an enlarged view of a portion shown in FIG. 4.

FIG. 6 is a cross-sectional view taken along B-B in FIG. 2.

FIG. 7 is an exploded perspective view of the electrical junction box from which a capacitor unit is excluded.

FIG. 8 is a perspective view showing a first shield case and a second shield case.

FIG. 9 is a perspective view showing the inside of the electrical junction box to which the first shield case and the second shield case are attached.

### DETAILED DESCRIPTION OF PREFERRED EMBODIMENTS

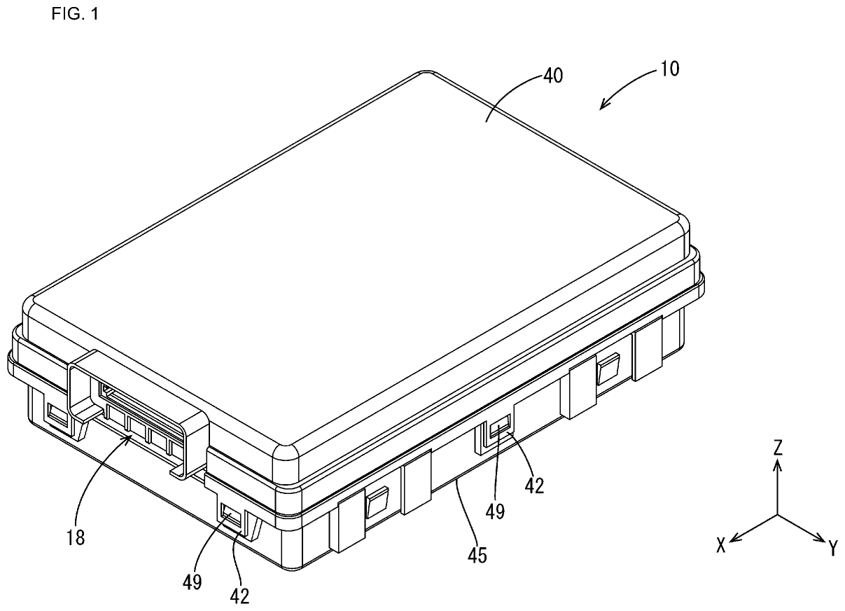

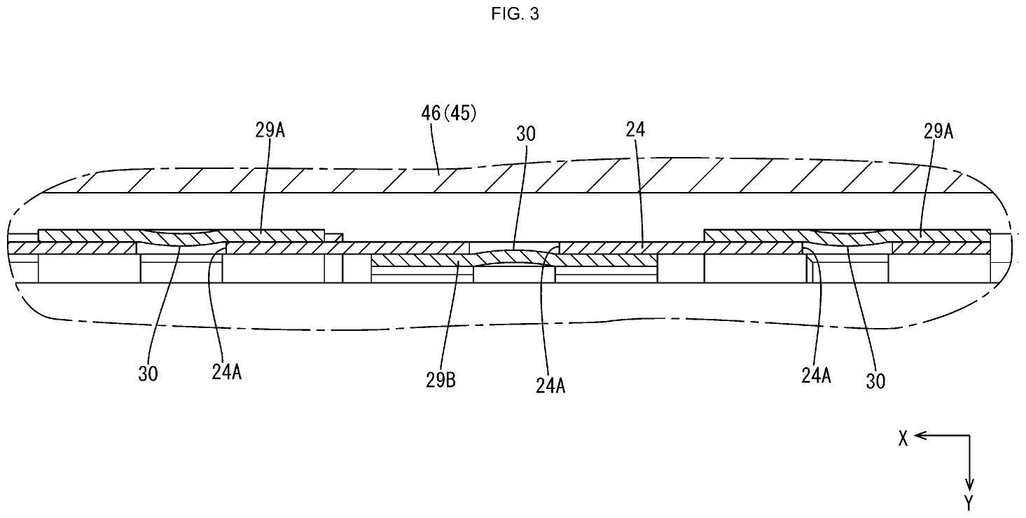

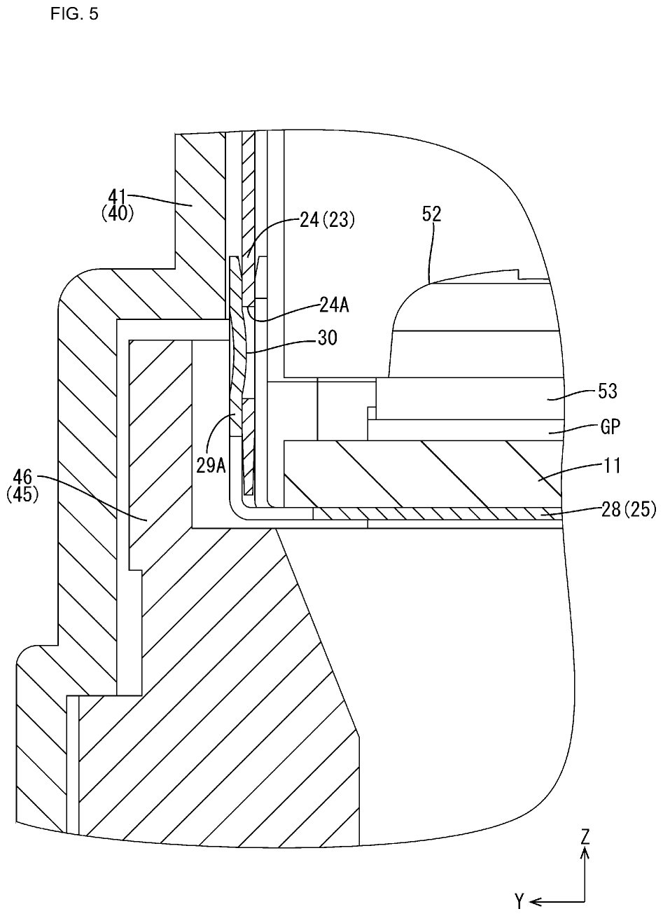

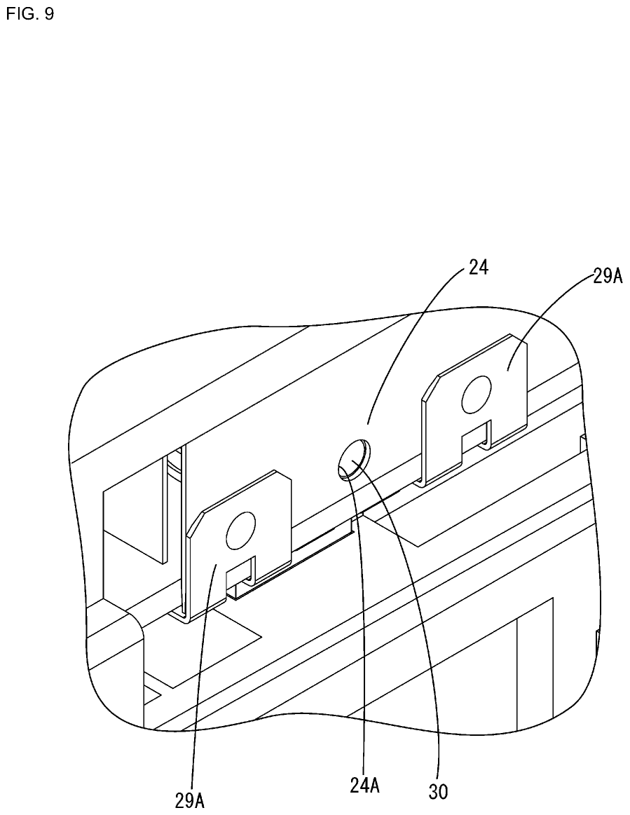

Embodiment 1 will be described with reference to FIGS. 1 to 9.

An electrical junction box 10 (FIG. 1) according to this embodiment is provided in a vehicle, e.g. an electric automobile or a hybrid automobile, separately from a main power source for supplying power to drive the vehicle, and can be used as an axially power source that can supply power to in-vehicle electric components, motors of devices, and the like. In the following description, “leftward”, “forward”, and “upward” respectively refer to the X-direction, the Y-direction, and the Z-direction in FIG. 1.

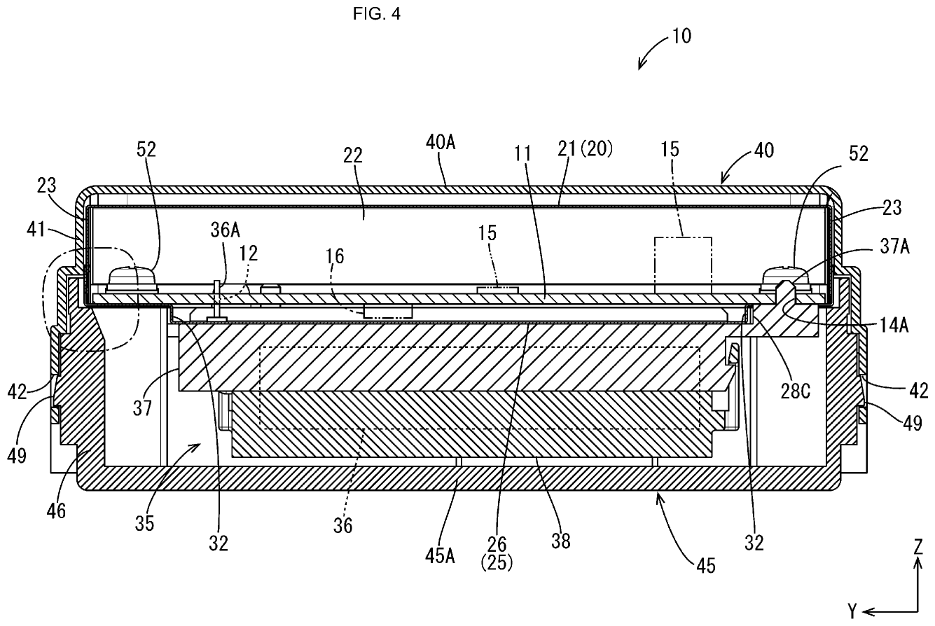

As shown in FIG. 4, the electrical junction box 10 includes a circuit board 11, a first shield case 20 arranged on the upper surface side (one side) of the circuit board 11, a second shield case 25 arranged on the lower surface side (the opposite side to the one side) of the circuit board 11, a capacitor unit 35 arranged on the lower side of the second shield case 25, and resin cases 40 and 45 that are made of a synthetic resin and in which the circuit board 11, the first shield case 20, the second shield case 25, and the capacitor unit 35 are accommodated.

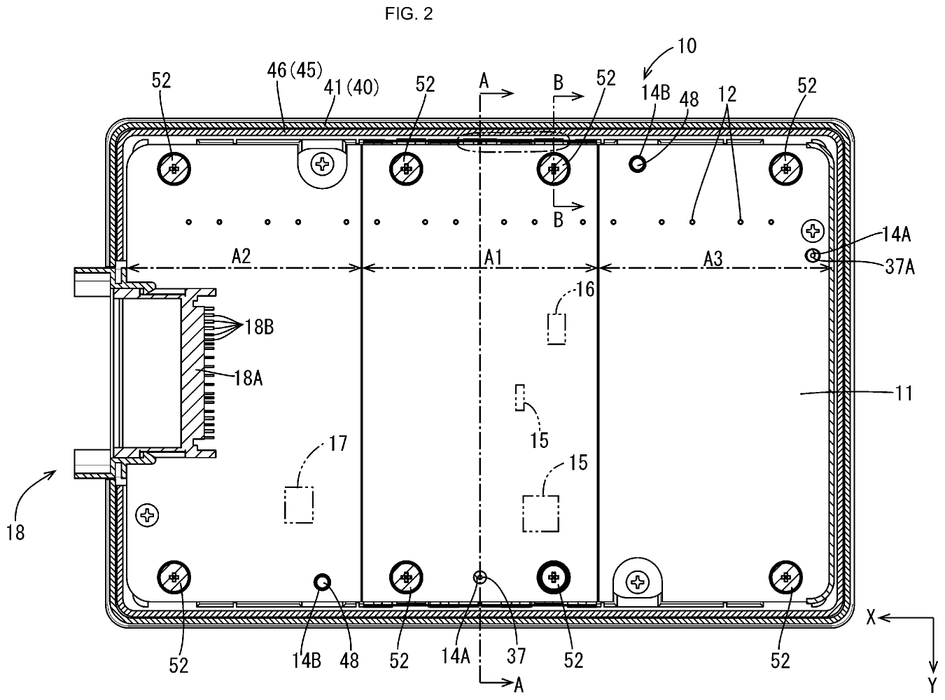

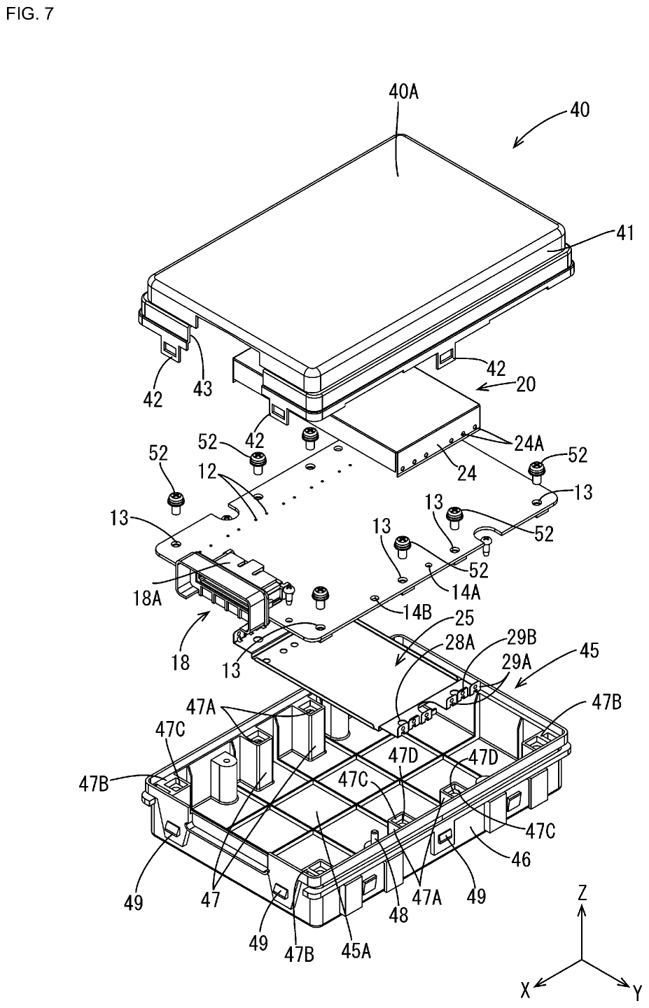

A printed circuit board in which a conductive path is formed on an insulating plate through printed wiring technology is used as the circuit board 11, and, as shown in FIG. 7, a plurality of terminal insertion holes 12 into which lead terminals 36A are inserted, a plurality of screw holes 13 through which axial portions of screws 52 are inserted, and a plurality of positioning holes 14A and 14B that position the circuit board 11 are formed to pass through the circuit board 11. The plurality of screw holes 13 and the plurality of positioning holes 14A and 14B are provided at intervals in a peripheral edge portion of the circuit board 11. Positioning pins 37A (positioning portions) of the capacitor unit 35 are inserted into the positioning holes 14A, and the positioning holes 14A position the capacitor unit 35 and the circuit board 11 relative to each other. Positioning pins 48 (positioning portions) of the second resin case 45 are inserted into the positioning holes 14B, and the positioning holes 14B position the second resin case 45 and the circuit board 11 relative to each other. As shown in FIGS. 2 and 4, a plurality of electronic components 15 to 17 are mounted on conductive paths on both sides of the circuit board 11. The plurality of electronic components 15 to 17 are constituted by FETs (Field Effect Transistors), resistors, diodes, coils, capacitors, and microcomputers, and their terminals are connected to the conductive paths of the circuit board 11. As shown in FIG. 2, in the circuit board 11, the electronic components 15 such as FETs that are likely to produce noise through switching are mounted in a shielded area A1 covered by the first shield case 20 and the second shield case 25, and the electronic component 17 that is unlikely to produce noise is mounted in non-shielded areas A2 and A3 other than the shielded area A1. The electronic component 16, which is low profile (has a small height in the up-down direction), compared to the shielded area A1 on the upper surface side of the circuit board 11, is mounted in the shielded area A1 on the lower surface side of the circuit board 11. Examples of the low profile electronic component 16 include resistors, diodes, and low profile capacitors. Note that the circuit board 11 is not limited to a printed circuit board, and a circuit board may be formed by placing a bus bar composed of a plate material made of a metal such as copper or a copper alloy on a printed circuit board, for example.

A connector 18 is fixed to a front end of the circuit board 11. The connector 18 includes a housing 18A that is open in a hood shape, and connector terminals 18B fixed to the housing 18A. The connector terminals 18B are connected to the conductive paths of the circuit board 11 due to the connector terminals 18B being soldered to a land portion of the circuit board 11.

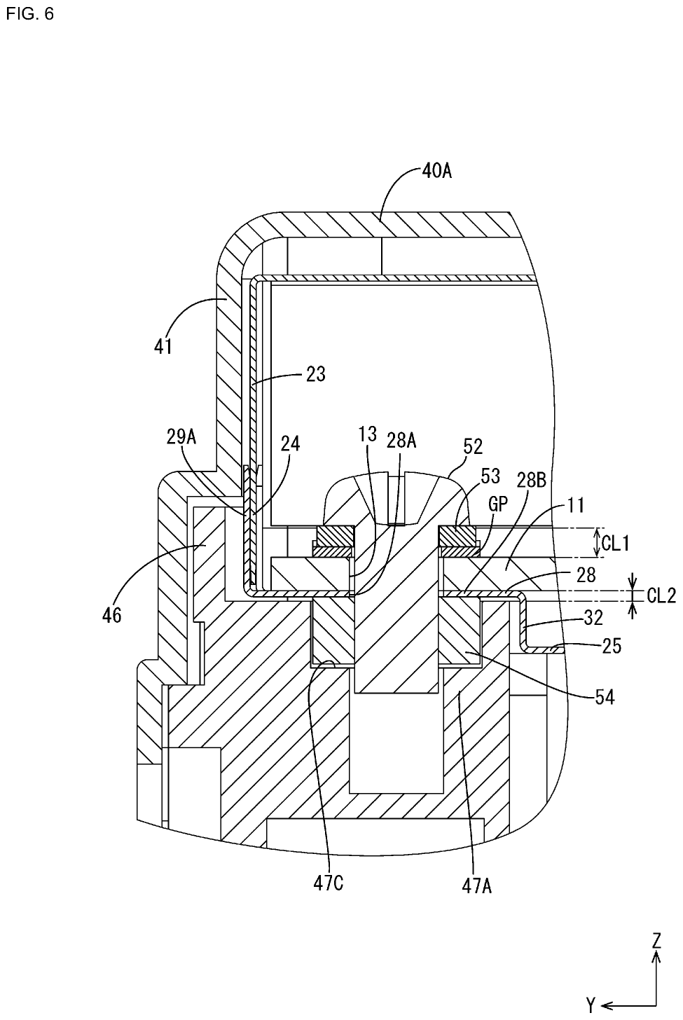

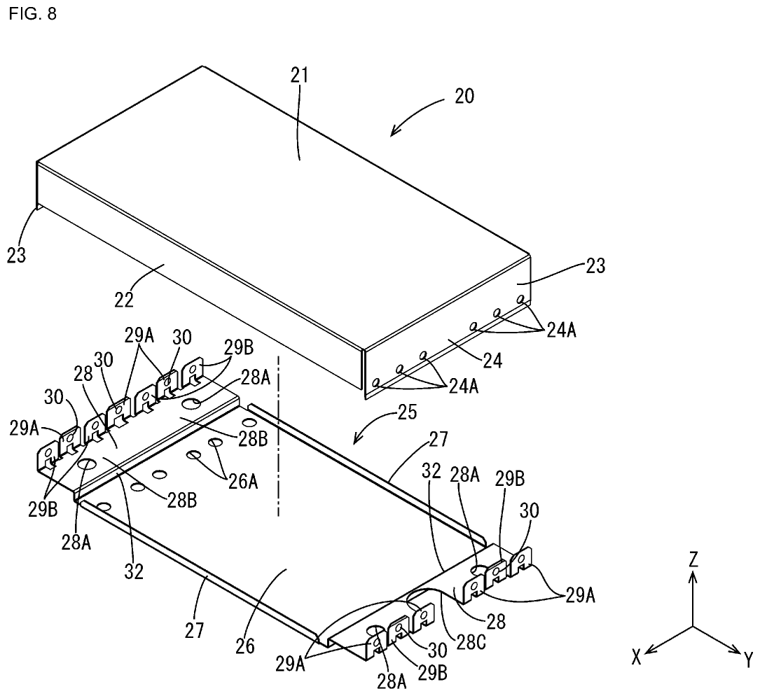

The first shield case 20 is made of a metal such as iron, stainless steel, or aluminum, and has a size to cover the shielded area A1 of the upper surface of the circuit board 11, and, as shown in FIG. 8, the first shield case 20 includes a rectangular top plate 21, side wall portions 22 and 22 that extend downward from both side end portions of the top plate 21, and end wall portions 23 and 23 that extend downward from front and rear end portions of the top plate 21. As shown in FIG. 6, the end wall portions 23 and 23 extend downward of the side wall portions 22 and 22, and a clearance CL1 is formed between the side wall portions 22 and 22 and the upper surface of the circuit board 11. The lower end portion side (the front end portion side) of the end wall portions 23 and 23 serve as a lock portion 24, and, as shown in FIG. 8, circular lock holes 24A that pass through a lock portion 24 are horizontally arranged side-by-side.

The second shield case 25 is made of a metal such as iron, stainless steel, or aluminum, and includes a rectangular opposing portion 26 disposed to face a lower surface of the circuit board 11 at an interval, a pair of side wall portions 27 and 27 that extend upward from both side edge portions of the opposing portion 26, overlapping portions 28 and 28 that extend in the front-rear direction via the step-shaped step portion 32 with respect to the opposing portion 26 and are placed on the circuit board 11 in an intimate contact state, and a plurality of locking pieces 29A and 29B that are provided at front end portions of the overlapping portions 28 and 28 and extend upward (in a direction that intersects with the plate surfaces of the overlapping portions 28 and 28). A plurality of through-holes 26A into which terminals are insertable are arranged side-by-side on one overlapping portion 28 side of the opposing portion 26. The height of the side wall portions 27 and 27 is smaller than that of the step portion 32, and, as shown in FIG. 6, a clearance CL2 is formed between the upper ends (front ends) of the side wall portions 27 and 27 and the lower surface of the circuit board 11 in a state in which the second shield case 25 is attached to the circuit board 11.

The overlapping portions 28 and 28 are placed on a front end portion and a rear end portion in the intermediate portion of the circuit board 11 in the left-right direction, and include fastening portions 28B that are screwed with screws 52. A plurality of screw holes 28A into which axial portions of the screws 52 are inserted pass through the fastening portions 28B. As shown in FIG. 8, a recess 28C allowing room for the head of the screw 52 when the capacitor unit 35 is screwed is cut out from one overlapping portion 28. As shown in FIG. 6, the screws 52 are inserted into the screw holes 13 and 28A in the circuit board 11 and the overlapping portions 28 and 28 with washers 53 inserted over the axial portions of the screws 52, and the circuit board 11 provided with a ground pattern GP and the fastening portions 28B are held between the heads of the screws 52 and nuts 54 through fastening with the nuts 54. Accordingly, the second shield case 25 is connected to the ground potential via the ground pattern GP.

As shown in FIG. 8, the plurality of locking pieces 29A and 29B are configured such that the locking pieces 29A and the locking pieces 29B are provided in an alternating manner in the left-right direction, and gaps are formed between the positions of the locking pieces 29A and the positions of the locking pieces 29B in the front-rear direction, and multiple rows of first locking pieces 29A and multiple rows of second locking pieces 29B are provided. The lock portions 24 of the first shield case 20 can be held between multiple rows of the first locking pieces 29A and multiple rows of the second locking pieces 29B. The first locking pieces 29A and the second locking pieces 29B each have a protrusion 30 that protrudes toward the lock portion 24 side (on the inner side thereof). Recesses corresponding to the shape of the protrusions 30 are formed in the surfaces of the locking pieces 29A and 29B on the opposite side to the protrusions 30. When the end wall portions 23 and 23 of the first shield case 20 are inserted into gaps between the first locking pieces 29A and the second locking pieces 29B, the protrusions 30 come into contact with the end wall portions 23 and 23, and the lock portions 24 are inserted between the first locking pieces 29A and the second locking pieces 29B while slightly elastically deforming the first locking pieces 29A and the second locking pieces 29B. Also, the first locking pieces 29A and the second locking pieces 29B are elastically restored due to the protrusions 30 being fitted into the plurality of lock holes 24A in the lock portions 24, and the first shield case 20 and the second shield case 25 are held in an assembled state. The lock portions 24 are in contact with the first locking pieces 29A and the second locking pieces 29B in this state, and thus the first shield case 20 is electrically connected to the ground potential via the second shield case 25, and detachment of the first shield case 20 and the second shield case 25 is restricted due to the protrusions 30 being fitted into the lock holes 24A. The first shield case 20 and the second shield case 25 can be formed by punching a thin metal plate material into an expanded shape using a press machine and then performing bending processing. Note that the protrusions 30 can be formed when punching the metal plate material using a press machine, for example.

As shown in FIG. 4, the capacitor unit 35 includes a plurality of capacitors 36 such as an electric double layer capacitor and a lithium ion capacitor, and a capacitor holder 37 that is made of a synthetic resin and holds the plurality of capacitors 36 side-by-side, for example. The capacitors 36 have a round columnar shape, for example, and each have a pair of positive and negative lead terminals 36A. The capacitor holder 37 includes a plurality of recessed portions (not shown) to which the plurality of capacitors 36 are fitted in a state in which the plurality of capacitors 36 are arranged side-by-side, and is covered by a capacitor cover 38 that restricts detachment of the plurality of capacitors 36. The capacitor holder 37 is provided with a positioning pin 37A that enters the recess 28C in the second shield case 25, and is inserted into the positioning hole 14A to position the relative positions of the circuit board 11 and the capacitor unit 35.

As shown in FIG. 7, the resin cases 40 and 45 include a first resin case 40 and a second resin case 45 that is fitted to the first resin case 40. The first resin case 40 has a box shape that is open on the downward side, and includes a peripheral wall portion 41 that has a rectangular cylindrical shape and extends downward from the peripheral edge of a rectangular plate-shaped ceiling wall 40A. A plurality of frame-shaped locking frames 42 capable of flexural deformation are provided at intervals around the entire periphery of a lower end portion of the peripheral wall portion 41. A lead-out recess 43 from which a connector 18 is led out is cut out from the peripheral wall portion 41 of the first resin case 40.

The second resin case 45 includes a rectangular plate-shaped bottom wall 45A and a rectangular cylindrical rising wall 46 that rises upward from the entire peripheral edge of the bottom wall 45A. A plurality of boss portions 47A and 47B and the positioning pins 48 are provided inside the rising wall 46. The plurality of boss portions 47A and 47B and the positioning pins 48 are provided at intervals in the circumferential direction, and are formed at positions adjacent to the rising wall 46. Upper portions of the plurality of boss portions 47A and 47B are provided with recesses 47C for accommodating nuts 54 in a state in which rotation of the nuts 54 is restricted, and recesses 47D that allow room for the axial portions of the screws 52. The positioning pins 48 have a rod shape, and are inserted into the positioning holes 14A and 14B in the circuit board 11 to position the circuit board 11. An outer periphery of the rising wall 46 of the second resin case 45 is provided with locking protrusions 49 that lock the locking frames 42 to restrict detachment of the first resin case 40.

Assembly of the electrical junction box 10 will be described below.

The overlapping portions 28 and 28 of the second shield case 25 are placed on the plurality of boss portions 47A in a state in which the capacitor unit 35 is accommodated in the second resin case 45, and the nuts 54 are respectively accommodated in the recesses 47C in the second resin case 45. Then, the circuit board 11 on which the connector 18 is mounted and the plurality of electronic components 15 to 17 are mounted is placed on the second shield case 25 such that the positioning pins 37A and 48 pass through the positioning holes 14A and 14B (see FIG. 7). Then, the axial portions of the screws 52 are inserted into the screw holes 13 and the screw holes 28A, and the circuit board 11 and the overlapping portions 28 and 28 are fastened to the plurality of boss portions 47A with the screws 52. Furthermore, the boss portions 47B and the like are also fastened with the screws 52 to fix the circuit board 11 to the second resin case 45.

Then, when the first shield case 20 is fitted to the second shield case 25 from above the circuit board 11, the lock portions 24 of the first shield case 20 are held between the first locking pieces 29A and the second locking pieces 29B of the second shield case 25, and the protrusions 30 of the first locking pieces 29A and the second locking pieces 29B are fitted to the lock holes 24A. Accordingly, the lock portions 24 are locked between the first locking pieces 29A and the second locking pieces 29B, and the shield cases 20 and 25 are connected to the ground potential. Then, the electrical junction box 10 is formed as a result of the second resin case 45 being covered with the first resin case 40, and hole edges of the locking frames 42 of the first resin case 40 being locked to the locking protrusions 49 of the second resin case 45 (FIG. 1).

According to this embodiment, the following effects can be obtained.

The electrical junction box 10 includes the circuit board 11 that has a conductive path and on which the electronic components 15 to 17 are mounted, the conductive first shield case 20 covering one side of the circuit board 11, a conductive second shield case 25 covering the opposite side of the circuit board 11 to the one side, the first resin case 40 that covers the first shield case 20 and is made of resin, and the second resin case 45 that covers the second shield case 25 and is made of resin.

According to this embodiment, both sides of the circuit board 11 are covered by the first shield case 20 and the second shield case 25, and the outer side of the first shield case 20 and the second shield case 25 is covered by the resin cases 40 and 45, and thus the shielded areas A1 on both sides of the circuit board 11 can be provided with the shielding function, and the weight of the electrical junction box 10 can be reduced compared to a configuration in which a metal case is used as the outer cover of the electrical junction box 10. Also, it is possible to use a thin metal plate member for the shield cases 20 and 25 compared to a configuration in which a metal housing is used as an outer cover of the electrical junction box 10, and thus the shield cases 20 and 25 can be easily shaped and manufacturing costs can be reduced.

Also, a plurality of the electronic components 15 to 17 are provided, and include FETs or the like (high-noise components), and coils or the like (low-noise components) whose noise is smaller than that of FETs, and at least one of the first shield case 20 and the second shield case 25 covers the plate surface of the circuit board 11 so as to include the shielded area A1 where FETs are mounted, which is smaller than the entire area of the circuit board 11.

Doing this makes it possible to further reduce the weight and manufacturing costs of the electrical junction box 10 compared to a configuration in which the entire area of the circuit board 11 is covered by the shield case.

Also, the first shield case 20 (one of the first and second shield cases 20 and 25) includes plate-shaped lock portions 24, and the second shield case 25 (the other of the first and second shield cases 20 and 25) includes the first locking pieces 29A and the second locking pieces 29B that hold the lock portions 24 therebetween, and the first locking pieces 29A and the second locking pieces 29B are provided side-by-side along the lock portions 24.

Doing this makes it possible to simplify the task of attaching.../operation to attach the first shield case 20 and the second shield case 25, and to maintain the state in which the first shield case 20 and the second shield case 25 are fitted to each other.

Also, the conductive path includes the ground pattern GP connected to the ground potential, and the second shield case 25 (at least one of the first and second shield cases 20 and 25) includes the fastening portions 28B that are screwed to the circuit board 11 and connected to the ground pattern GP.

Doing this makes it possible to connect the shield cases 20 and 25 to the ground potential using the configuration for fixing the second shield case 25 (at least one of the first and second shield cases 20 and 25) to the circuit board 11.

Also, the second shield case 25 (at least one of the first and second shield cases 20 and 25) includes the fastening portions 28B and the opposing portion 26 that faces the circuit board 11 at an interval, and the step portion 32 is formed between the fastening portions 28B and the opposing portion 26.

As a result, the space in which the electronic component 16 is accommodated can be formed between the circuit board 11 and the opposing portion 26 due to the step portion 32.

Also, (at least one of) the first shield case 20 and the second shield case 25 includes the side wall portions 22 (27) that each have a plate surface extending in a direction that intersects with the plate surface of the circuit board 11, and end portions of the side wall portions 22 (27) on the circuit board 11 side are provided with the clearances CL1 and CL2 between the end portions and the circuit board 11.

Doing this makes it possible to suppress a low profile circuit caused by contact between conductive paths, which have a potential higher than the ground potential, on the upper surface and the lower surface of the circuit board 11, and the leading end portions of the side wall portions 22 (27) of the shield cases 20 and 25.

Also, the capacitors 36 are accommodated between the second shield case 25 and the second resin case 45.

Doing this makes it possible to dispose the second shield case 25 and the electronic component 16 in the gaps between the circuit board 11 and the capacitors 36.

### Other Embodiments

The technology described in this specification is not merely limited to the embodiments described above using the foregoing description and drawings, and embodiments such as the following are also encompassed in the technical scope of this specification.

Although a configuration is adopted in which the electronic component 16 is mounted on the back side (the shielded area A1 covered by the second shield case 25) of the circuit board 11, there is no limitation thereto, and a configuration may be adopted in which no electronic components are mounted in the shielded area A1 on the back side of the circuit board 11, and only the conductive path is arranged thereon.

The range of the shielded areas A1 of the circuit board 11 covered by the first shield case 20 and the second shield case 25 is not limited to the configuration of the above-described embodiment. A configuration may be adopted in which one or both of the first shield case 20 and the second shield case 25 covers the entire circuit board 11, for example.

Although the lock holes 24A in the first shield case 20 are through-holes, there is no limitation thereto, and a configuration may be adopted in which the protrusions 30 are locked to the locking recesses that do not pass through the first shield case 20.

Although the first shield case 20 is provided with the lock holes 24A and the second shield case 25 is provided with the locking pieces 29A and 29B, there is no limitation thereto, and the first shield case 20 may be provided with a locking piece and the second shield case 25 may be provided with a lock hole to which a locking piece is locked.

Although the second shield case 25 is provided with the fastening portions 28B connected to the ground potential, there is no limitation thereto, and the first shield case 20 may be provided with a fastening portion connected to the ground potential. Also, although the second shield case 25 is provided with the step portion 32, the first shield case 20 may be provided with a step portion.

1. An electrical junction box comprising:
a circuit board that has a conductive path and on which an electronic component is mounted;
a conductive first shield case covering one side of the circuit board;
a conductive second shield case covering an opposite side of the circuit board to the one side;
a first resin case that covers the first shield case and is made of resin; and
a second resin case that covers the second shield case and is made of resin.

2. The electrical junction box according to claim 1,
wherein the electronic component is provided in plural and includes a high-noise component and a low-noise component whose noise is smaller than that of the high-noise component, and at least one of the first shield case and the second shield case covers a surface of the circuit board so as to include an area where the high-noise component is mounted, which is an area smaller than the entire area of the circuit board.

3. The electrical junction box according to claim 1, wherein one of the first shield case and the second shield case includes a plate-shaped lock portion, the other of the first shield case and the second shield case includes a first locking piece and a second locking piece that hold the lock portion therebetween, and the first locking piece and the second locking piece are arranged side-by-side along the lock portion.

4. The electrical junction box according to claim 1, wherein the conductive path includes a ground pattern connected to a ground potential, and at least one of the first shield case and the second shield case includes a fastening portion that is screwed to the circuit board and connected to the ground pattern.

5. The electrical junction box according to claim 4, wherein at least one of the first shield case and the second shield case includes the fastening portion and an opposing portion that faces the circuit board at an interval, and a step portion is formed between the fastening portion and the opposing portion.

6. The electrical junction box according to claim 1, wherein at least one of the first shield case and the second shield case includes a side wall portion that has a plate surface extending in a direction that intersects with a plate surface of the circuit board, and an end portion of the side wall portion on the circuit board side is provided with a clearance between the end portion and a surface of the circuit board.

7. The electrical junction box according to claim 1, wherein a capacitor is accommodated between the second shield case and the second resin case.

8. The electrical junction box according to claim 2, wherein one of the first shield case and the second shield case includes a plate-shaped lock portion, the other of the first shield case and the second shield case includes a first locking piece and a second locking piece that hold the lock portion therebetween, and the first locking piece and the second locking piece are arranged side-by-side along the lock portion.

9. The electrical junction box according to claim 2, wherein the conductive path includes a ground pattern connected to a ground potential, and at least one of the first shield case and the second shield case includes a fastening portion that is screwed to the circuit board and connected to the ground pattern.

10. The electrical junction box according to claim 3, wherein the conductive path includes a ground pattern connected to a ground potential, and at least one of the first shield case and the second shield case includes a fastening portion that is screwed to the circuit board and connected to the ground pattern.

11. The electrical junction box according to claim 2, wherein at least one of the first shield case and the second shield case includes a side wall portion that has a plate surface extending in a direction that intersects with a plate surface of the circuit board, and an end portion of the side wall portion on the circuit board side is provided with a clearance between the end portion and a surface of the circuit board.

12. The electrical junction box according to claim 3, wherein at least one of the first shield case and the second shield case includes a side wall portion that has a plate surface extending in a direction that intersects with a plate surface of the circuit board, and an end portion of the side wall portion on the circuit board side is provided with a clearance between the end portion and a surface of the circuit board.

13. The electrical junction box according to claim 4, wherein at least one of the first shield case and the second shield case includes a side wall portion that has a plate surface extending in a direction that intersects with a plate surface of the circuit board, and an end portion of the side wall portion on the circuit board side is provided with a clearance between the end portion and a surface of the circuit board.

14. The electrical junction box according to claim 5, wherein at least one of the first shield case and the second shield case includes a side wall portion that has a plate surface extending in a direction that intersects with a plate surface of the circuit board, and an end portion of the side wall portion on the circuit board side is provided with a clearance between the end portion and a surface of the circuit board.

15. The electrical junction box according to claim 2, wherein a capacitor is accommodated between the second shield case and the second resin case.

16. The electrical junction box according to claim 3, wherein a capacitor is accommodated between the second shield case and the second resin case.

17. The electrical junction box according to claim 4, wherein a capacitor is accommodated between the second shield case and the second resin case.

18. The electrical junction box according to claim 5, wherein a capacitor is accommodated between the second shield case and the second resin case.

19. The electrical junction box according to claim 6, wherein a capacitor is accommodated between the second shield case and the second resin case.
